(19) United States
(12) Patent Application Publication
(10) Pub. No.: US 2023/0034166 A1
(43) Pub. Date: Feb. 2, 2023

(54) TEST DEVICE AND PROCESS FOR TESTING THE CONFIGURATION OF AN EXTERNAL CIRCUIT FOR AN RC RECEIVER

(71) Applicant: Benjamin Maximus Son, Columbus, OH (US)

(72) Inventor: Benjamin Maximus Son, Columbus, OH (US)

(73) Assignee: Mr. Benjamin Maximus Son, Columbus, OH (US)

(21) Appl. No.: 17/391,008

(22) Filed: Aug. 1, 2021

(51) Int. Cl. G01R 19/14; G01R 19/165; G01R 19/155; G01R 31/319; G01R 31/317

(52) U.S. Cl. CPC G01R 19/14; G01R 19/16538; G01R 19/155; G01R 31/31905; G01R 31/31728

(57) ABSTRACT

A tool with three pins arranged in a row that three pinholes arranged in a row such as those found on a motor controller could easily connect to and disconnect from, that, when connected to a motor controller, identifies which of the three wires is positively charged, and whether the voltage difference is above 9 volts. Should one of the outer two wires be positively charged, and consequently not the middle one, or should the voltage difference be greater than 9 volts, then the motor controller would be faultily wired, consequently breaking any receiver that the motor controller connects to.

### FIELD OF TECHNOLOGY

The present disclosure generally relates to protecting receivers, and more particularly relates to protecting receivers by testing their corresponding motor controller for faulty wiring which would cause receiver breakage.

### DESCRIPTION OF THE RELATED ART

Receivers are circuit components that wirelessly receive data from another device known as a transmitter. In any device with a wireless data transmission connection, there is a receiver.

Therefore, cell phones, computers that can access the internet, televisions with remote controls, and wirelessly controlled robots all have receivers.

Wirelessly controlled robots typically have motors, which allow the motored robot to physically move itself and manipulate objects. When the motor needs to be controlled via a wireless connection, it is connected to a motor controller (“MCR”), which in turn connects to the receiver. The transmitter can then send signals to the receiver, which passes the signal data on to the motor controller. The motor controller supplies the motor with different amounts of power depending on the signals that it is sent. This configuration of parts allows the power supplied to a motor to be controlled wirelessly from a transmitter, thus allowing a robot to be wirelessly controlled.

The receiver-to-motor-controller connection typically is provided in the form of a three-wire Dupont connection. In a three-wire Dupont connection, three wires from the receiver are connected to respective terminal pins arranged in a parallel configuration, and three wires from the motor controller end are similarly connected to respective terminal receptors or pinholes that are arranged in a parallel configuration and configured to receive the respective pins from the receiver. This allows the three pins to be connected to, and disconnected from, the three pinholes repeatedly, which will make and break the connection between the receiver and motor controller repeatedly. A first of the three wires from the motor controller is electrically positive during operation, a second wire is electrically negative, and a third wire receives signal data from the receiver. Care should be taken when attaching the receiver and motor controller to the connectors. The positive wire must be in the middle of the three-pinhole arrangement, and the voltage difference between the positive wire and the negative must be less than the receiver's rated maximum voltage, which is typically 9 volts, or else the wiring configuration is faulty. A receiver that connects to a motor controller can be broken or otherwise made inoperable if it is connected to a motor controller with a faulty wiring configuration.

### SUMMARY

This invention relates to the protection of MCRs by testing whether the motor controllers they will be connected to, or the wiring configuration thereof, are faulty.

Such protection can typically be achieved by two functions, i.e., testing whether the positive wire (or a terminal receptor thereof) of the MCR is properly arranged in the middle of the three-pinhole arrangement, and testing whether the voltage difference between the positive and negative wires of the receiver is above 9 volts.

In an embodiment of the present invention henceforth known as the Receiver Protector (RP), the RP is a test device for testing the configuration of an external circuit for an RC receiver. It includes a three-pin male connector that is configured to connect to three female pins of the external circuit and a test circuit that is attached to the connector. The test circuit is configured to detect at least one of the following characteristics of the receiver: (a) which of the female pins is electrically positive, and (b) whether the voltage difference between the positive female pin and the other female pins is greater than a preset value, such as 9 volts.

More particularly, the RP is connected to a motor controller and lights one out of three LEDs, where each LED corresponds to each wire in the three-pinhole arrangement, and the LED that lights up corresponds to the wire that is positive. This informs the operator of the device whether the positive wire is in the middle position of the three pinholes, and if not in the middle, then it informs the operator which of the outer pinholes is positive.

When the RP connects to a motor controller and detects the location of the positive wire, it also determines whether the voltage difference between the positive wire and the negative wire exceeds 9 volts, lighting a fourth LED if it does exceed 9 volts. This informs the operator of the RP whether the voltage difference between the positive and the negative wires is greater than or less than 9 volts.

### BRIEF DESCRIPTION OF THE DRAWINGS

FIG. 1 is a diagram of the circuit of the RP according to one embodiment of the present invention.

FIG. 2 shows the RP connected to a direct current voltage source that is simulating a motor controller at a voltage below 9 volts with the positive wire at the top position, causing the corresponding top LED to light.

FIG. 3 shows the RP connected to a direct current voltage source that is simulating a motor controller at a voltage below 9 volts with the positive wire in the middle position, causing the corresponding middle LED to light.

FIG. 4 shows the RP connected to a direct current voltage source that is simulating a motor controller at a voltage below 9 volts with the positive wire at the bottom position, causing the corresponding bottom LED to light.

FIG. 5 shows the RP connected to a direct current voltage source that is simulating a motor controller at a voltage above 9 volts with the positive wire on the top, causing the corresponding leftmost red LED to light, as well as the LED at the far right, which signals a voltage higher than 9 volts, to light.

### DETAILED DESCRIPTION

The embodiment of the present invention known as the RP is illustrated by the accompanying drawings and will be described below in detail.

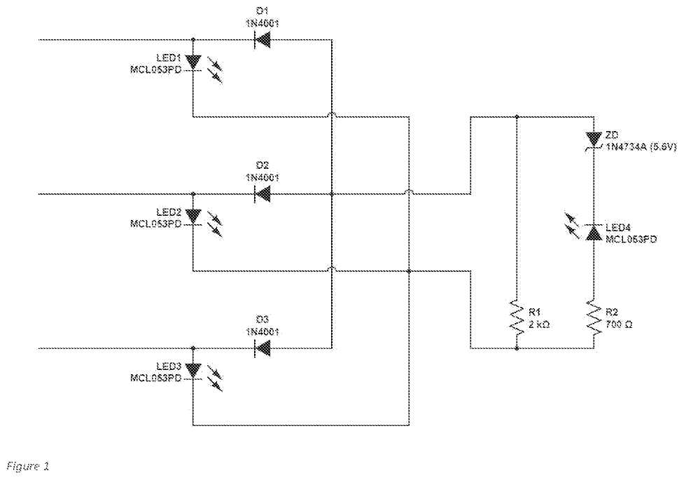

As shown in FIG. 1, The RP connects to a motor controller through the same type of connection that a receiver uses to connect to the motor controller in normal operation of the motor controller and receiver, i.e., a three-wire “Dupont” connection. In this case, the RP must have three parallel pins in a linear arrangement that can easily connect and disconnect from the three pinholes on the wires of the motor controller. These three pins are each soldered to one of three wires. Because each pinhole from the motor controller could be either the positive, negative, or signal pinhole, each of these three wires will be either the positive, negative, or signal wire.

Because the wiring of a motor controller can be faulty due to either misplacement of the positive wire or an excessive voltage difference between the positive and negative wires, the RP tests both the placement of the positive wire and the voltage difference.

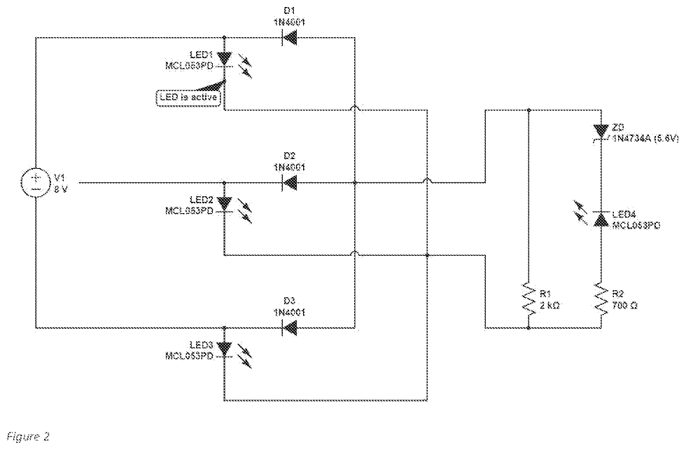

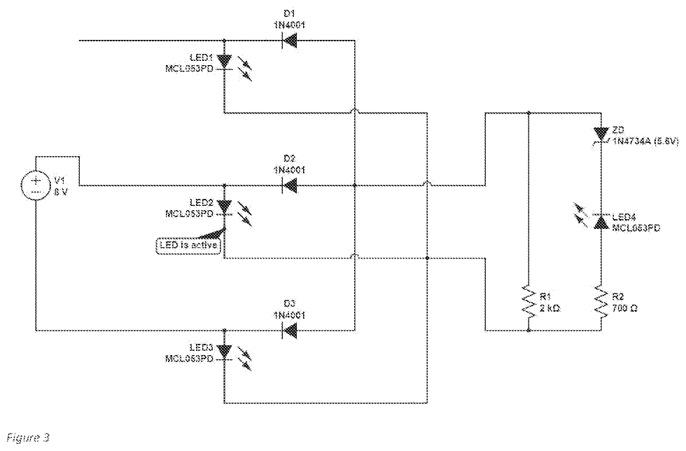

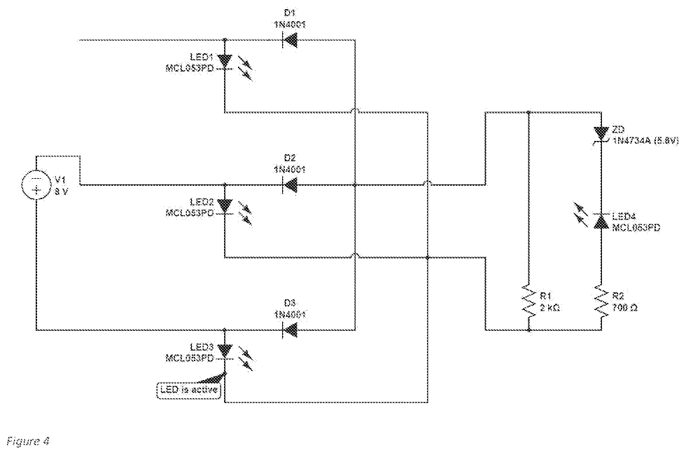

The RP has 3 red LEDs, in this case of model type MCL053PD, that each correspond to one of these three wires. When the RP connects to a motor controller, the pinhole that is positively charged causes its corresponding wire to be positively charged, which in turn lights up the corresponding LED as shown in FIG. 2, FIG. 3, and FIG. 4. The user of the RP will then see which LED is on, allowing him or her to know which pinhole is positively charged. If either of the outer pinholes is positively charged, the user will know that the wiring is faulty and needs fixed.

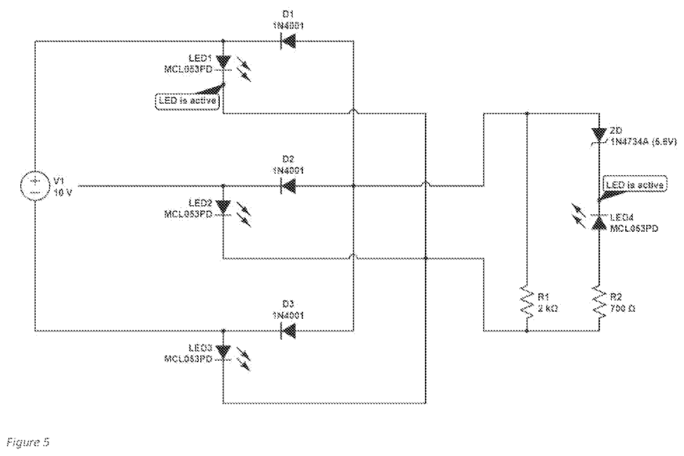

The RP also has an LED of model type MCL053PD that lights up when the applied voltage exceeds 9 volts, as shown in FIG. 5. This allows the user of the RP to know when the voltage is exceedingly high.

The circuitry of the RP is designed to fulfill both aforementioned functions.

Leading into the circuitry of the RP are the three wires that were soldered to the three pins. These wires each have an LED leading away from them. The other ends of those three LEDs are connected. The three wires not only have an LED leading away from them, but also a diode leading toward them, of model type 1N4001. The ends of these three diodes are also connected. This arrangement has three LEDs that each correspond to one of the wires. When a wire is positive, current runs through the LED leading away from the wire, lighting it, which alerts the user which of the pins is positive and effectively warns the user when the wiring is faulty due to a misplaced positive wire. When a wire is negative, current will run towards the wire from the diode leading toward the wire. The point where the ends of the LEDs converge will always be positive when a motor controller is connected to the RP. The point where the diodes leading towards the wires converge will always be negative when a motor controller is connected to the RP.

A 2,000-ohm resistor connects the point where the LEDs converge that is always positive with the point where the diodes converge that is always negative. In parallel with that resistor is a 5.6 volt Zener diode biased against the always positive point in series with a 700-ohm resistor in series with another MCL053PD red LED leading toward the negative point. When the voltage difference between the pins on the Dupont connector is below 9 volts, the Zener diode blocks current, preventing current from flowing through the 700-ohm resistor and the red LED. The current instead flows through the 2,000-ohm resistor. When the voltage difference between the pins at the start of the circuit exceeds 9 volts, the 5.6-volt Zener diode reaches its breakdown point, allowing current to flow through it, the 700-ohm resistor, and the red LED. This causes the red LED to emit light. In summary, the red LED will emit light when the voltage difference between the pins exceeds 9 volts but will not emit light when the voltage difference between the pins is below 9 volts or equal to 9 volts, thereby effectively warning the user when the voltage difference between the pins is dangerously high for a receiver.

I claim:

1. A test device for testing the configuration of an external circuit for an RC receiver, comprising:
a three-pin male connector that is configured to connect to three female pins of the external circuit, and
a test circuit attached to the connector that detects at least one of the following: which female pin is positive, and whether the voltage difference between the positive female pin and other female pins is greater than a preset value.

2. The test device of claim 1, wherein the circuit is configured to detect which pin is positive.

3. The test device of claim 1, wherein the circuit is configured to detect whether the voltage difference is greater than a preset value.

4. The test device of claim 3, wherein the preset value that the voltage difference is being compared against is between 7 and 11 volts.

5. The test device of claim 1, wherein the circuit detects which pin is positive and whether the voltage difference is greater than a preset value.

6. The test device of claim 5, wherein the preset value that the voltage difference is being compared against is between 7 and 11 volts.

7. The test device of claim 5, wherein the preset value that the voltage difference is being compared against is 9 volts; the circuit detects which pin is positive using red LEDs, and the circuit detects whether the voltage difference is greater than a preset value using a Zener diode in series with a red LED.

8. A method of testing the configuration of an external circuit for an RC receiver, the method comprising:
connecting a three-pin male connector to three female pins of the external circuit and thereby electrically connecting a test circuit to the external circuit;
detecting with the test circuit at least one of the following to determine that the external circuit is incorrectly wired: which female pin is positive, and whether the voltage difference between the positive female pin and other female pins is greater than a preset value;
reconfiguring the connection of the three female pins to the external circuit to correct the wiring thereof; and
connecting the external circuit to the RC receiver so that the external circuit is configured to receive signals from the RC receiver and initiate motions in response to such signals.
